(19) United States
(12) Patent Application Publication
(10) Pub. No.: US 2025/0308916 A1
(43) Pub. Date: Oct. 2, 2025

(54) SEMICONDUCTOR DEVICE MANUFACTURING METHOD AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Hiroki KOMATSU, Hakusan Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/823,940

(22) Filed: Sep. 4, 2024

(30) Foreign Application Priority Data
Apr. 2, 2024 (JP) 2024-059636

(51) Int. Cl. H01L 21/311; H01L 29/06; H01L 29/40

(52) U.S. Cl. CPC H01L 21/31111; H01L 21/31144; H10D 62/107; H10D 64/111

(57) ABSTRACT

A semiconductor device manufacturing method according to this embodiment includes forming a first insulation film, on a first face of a semiconductor substrate, such that a film thickness of the first insulation film at a step portion of a protrusion portion provided in a first region of the first face is thinner than a film thickness of the first insulation film at an upper surface of the protrusion portion or a film thickness of the first insulation film at a second region of the first face, the second region different from the first region. The manufacturing method includes removing part of the first insulation film using a mask material as a mask to form an opening portion of the first insulation film and a projection portion of the first insulation film. The manufacturing method includes removing the second insulation film together with part of the projection portion.

### CROSS REFERENCE TO RELATED APPLICATIONS

This application is based upon and claims the benefit of priority from the prior Japanese Patent Application No. 2024-059636, filed on Apr. 2, 2024, the entire contents of which are incorporated herein by reference.

### FIELD

The embodiments of the present invention relate to a semiconductor device manufacturing method and a semiconductor device.

### BACKGROUND

In semiconductor devices such as IGBTs (insulated gate bipolar transistors), it may be difficult to form a flat structure by CMP (chemical mechanical polishing) due to structural differences between the cell region and the termination region.

### BRIEF DESCRIPTION OF THE DRAWINGS

FIG. 1A is a cross-sectional view showing an example of a semiconductor device manufacturing method according to a first embodiment;

FIG. 1B is a cross-sectional view showing an example of a semiconductor device manufacturing method following FIG. 1A;

FIG. 1C is a cross-sectional view showing an example of a semiconductor device manufacturing method following FIG. 1B;

FIG. 1D is a cross-sectional view showing an example of a semiconductor device manufacturing method following FIG. 1C;

FIG. 1E is a cross-sectional view showing an example of a semiconductor device manufacturing method following FIG. 1D;

FIG. 1F is a cross-sectional view showing an example of a semiconductor device manufacturing method following FIG. 1E;

FIG. 1G is a cross-sectional view showing an example of a semiconductor device manufacturing method following FIG. 1F;

FIG. 1H is a cross-sectional view showing an example of a semiconductor device manufacturing method following FIG. 1G;

FIG. 1I is a cross-sectional view showing an example of a semiconductor device manufacturing method following FIG. 1H;

FIG. 2A is a cross-sectional view showing an example of a semiconductor device manufacturing method according to a first comparative example of the first embodiment;

FIG. 2B is a cross-sectional view showing an example of a semiconductor device manufacturing method following FIG. 2A;

FIG. 3A is a cross-sectional view showing an example of a semiconductor device manufacturing method according to a second comparative example of the first embodiment;

FIG. 3B is a cross-sectional view showing an example of a semiconductor device manufacturing method following FIG. 3A;

FIG. 4A is a cross-sectional view showing an example of a semiconductor device manufacturing method according to a second embodiment;

FIG. 4B is a cross-sectional view showing an example of a semiconductor device manufacturing method following FIG. 4A;

FIG. 4C is a cross-sectional view showing an example of a semiconductor device manufacturing method following FIG. 4B;

FIG. 4D is a cross-sectional view showing an example of a semiconductor device manufacturing method following FIG. 4C; and

FIG. 5 is a cross-sectional view showing an example of a semiconductor device manufacturing method according to a first comparative example of the second embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device manufacturing method according to this embodiment includes forming a semiconductor layer of a first conductivity type on a protrusion portion of a semiconductor substrate having a first face and the protrusion portion provided in a first region of the first face. The manufacturing method includes forming a first insulation film, on the first face, such that a film thickness of the first insulation film at a step portion of the protrusion portion is thinner than a film thickness of the first insulation film at an upper surface of the protrusion portion or a film thickness of the first insulation film at a second region of the first face different from the first region. The manufacturing method includes forming a mask material on the first insulation film. The manufacturing method includes removing the mask material on the protrusion portion. The manufacturing method includes removing part of the first insulation film using a mask material as a mask to form an opening portion of the first insulation film and a projection portion of the first insulation film, the opening portion exposing an upper surface of the protrusion portion, the projection portion projecting from an edge portion of the opening portion to an opposite side of the semiconductor substrate. The manufacturing method includes forming a second insulation film on the protrusion portion and on the first insulation film. The manufacturing method includes removing the second insulation film together with part of the projection portion.

### First Embodiment

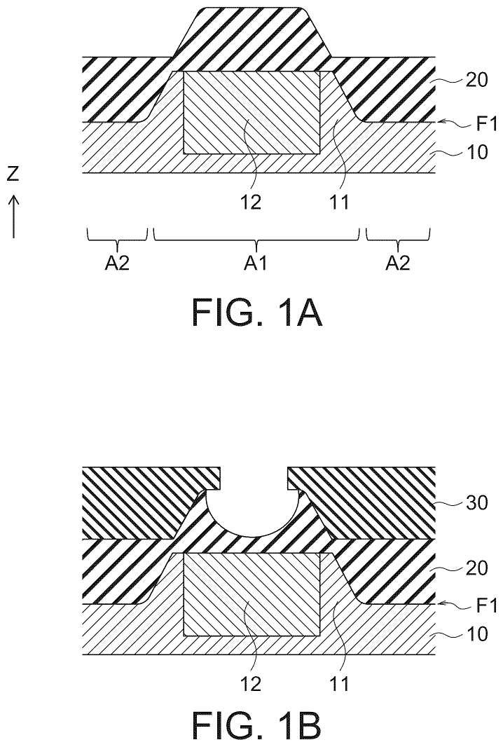

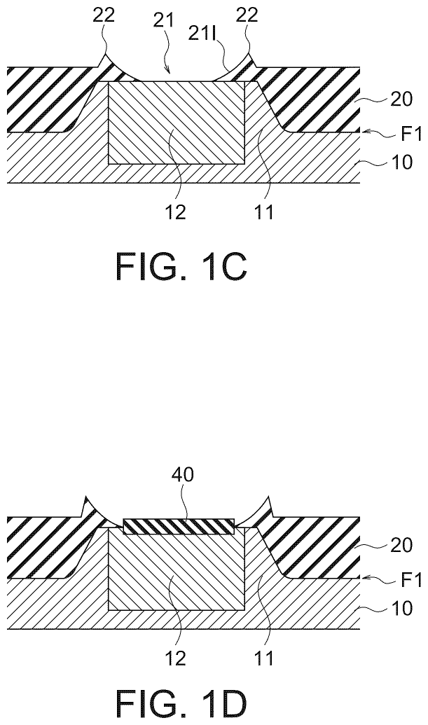

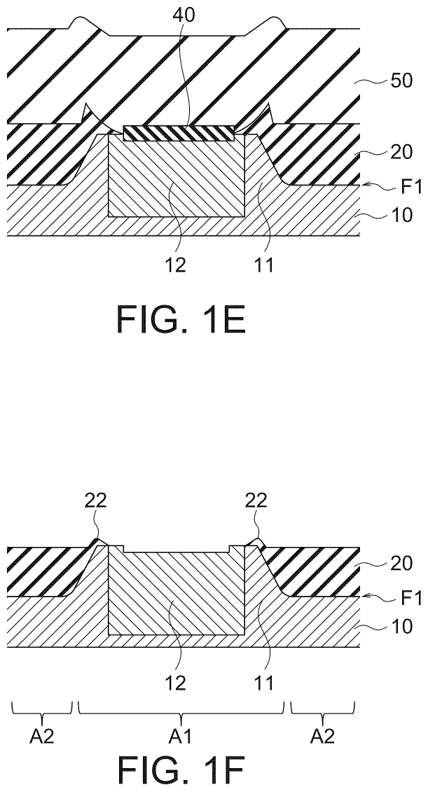

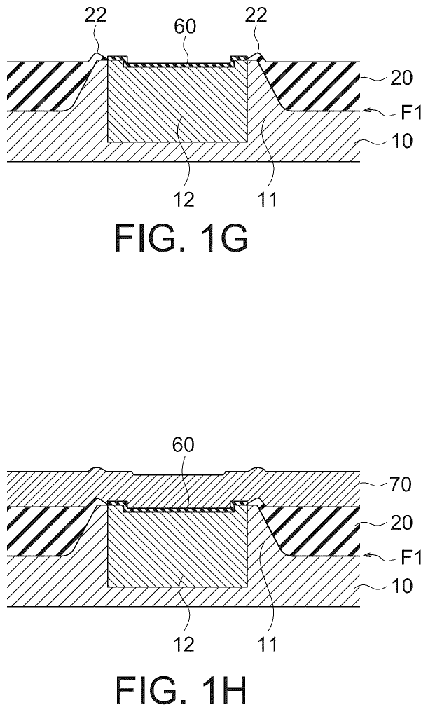

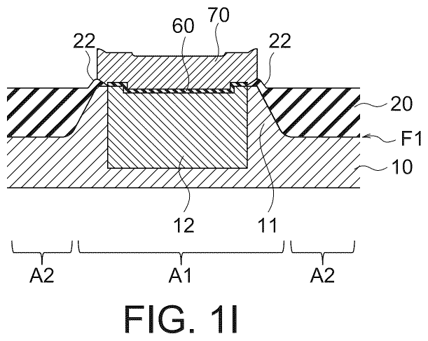

FIGS. 1A to 1I are cross-sectional views showing an example of a semiconductor device manufacturing method according to a first embodiment. The semiconductor device is, for example, an IGBT (insulated gate bipolar transistor). FIGS. 1A to 1I show the termination region of an IGBT.

A Z axis shown in FIG. 1A represents a Z direction. The Z direction may be described as the upward direction and the opposite direction as the downward direction.

A semiconductor substrate 10 has a face F1 and a protrusion portion 11. The protrusion portion 11 is provided in a region A1 of the face F1 and protrudes from the face F1 in the Z direction. Regions A2 of the face F1, which are different from the region A1, are regions where no protrusion portion 11 is provided. The regions A1 and A2 are included in the termination region. The semiconductor substrate 10 is, for example, a silicon (Si) substrate.

In the example shown in FIG. 1A, a semiconductor layer 12 of a first conductivity type is formed on the protrusion portion 11. The semiconductor layer 12 is formed to a predetermined depth from the upper surface of the protrusion portion 11. The semiconductor layer 12 functions as a guard ring for canceling electric charge. The first conductivity type is, for example, p-type. The semiconductor layer 12 is formed, for example, by implanting an impurity of the first conductivity type (p-type).

First, as shown in FIG. 1A, an insulation film 20 is formed on the face F1. The insulation film 20 is a buried oxide film. The insulation film 20 is formed so that the film thickness at the step portions (side portions) of the protrusion portion 11 is thinner than the film thickness on the upper surface of the protrusion portion 11 or that in the regions A2. The height of the upper surface of the insulation film 20 in the regions A2 is higher than the height of the upper surface of the protrusion portion 11. The insulation film 20 is formed, for example, by an HDP (high density plasma) method. The HDP film is formed thinly near the steps. The insulation film 20 is, for example, an oxide film such as a silicon oxide film.

Next, as shown in FIG. 1B, a resist 30 (mask material) is formed on the insulation film 20, and the resist 30 above the protrusion portion 11 is removed. Then, the resist 30 is used as a mask to remove part of the insulation film 20. The part of the insulation film 20 is removed by isotropic etching such as wet etching. Note that FIG. 1B shows the etching in progress.

Next, as shown in FIG. 1C, removing part of the insulation film 20 forms an opening portion 21 and projection portions 22 in the insulation film 20. The resist 30 is then removed. The opening portion 21 exposes the upper surface of the protrusion portion 11. The projection portions 22 project from the edge portions of the opening portion 21 to the opposite side of the semiconductor substrate 10. The angle of each inner side surface 211 of the opening portion 21 with respect to the upper surface (horizontal surface) of the protrusion portion 11 is, for example, 300 to 400.

In the process shown in FIG. 1A, since the insulation film 20 at the step portions of the protrusion portion 11 is thin, the etching amount can be reduced even when a projection portion 22 is formed that protrudes slightly from the upper surface of the protrusion portion 11.

Next, as shown in FIG. 1D, an insulation film 40 is formed on the protrusion portion 11. The insulation film 40 is formed, for example, by oxidation treatment. The insulation film 40 is, for example, an oxide film. Here, the insulation film 40 is a film formed in processing in a cell region different from the termination region. The insulation film 40 does not necessarily need to be formed.

Next, as shown in FIG. 1E, an insulation film 50 is formed on the protrusion portion 11 (insulation film 40) and the insulation film 20. The insulation film 50 is, for example, formed by CVD (chemical vapor deposition). The insulation film 50 is, for example, an LP-TEOS (low-pressure tetra-ethoxy silane) film. The insulation film 50 functions, for example, as a mask material in processing (for example, RIE (reactive ion etching)) in a cell region different from the termination region.

Next, as shown in FIG. 1F, the insulation film 50 is removed together with part of the projection portion 22. For example, the insulation film 50 remaining after RIE is completely removed by wet etching. In the wet etching, part of the insulation film 20 including the projection portion 22 is also removed at the same time as the insulation film 50 is. The height of the upper surface of the insulation film 20 in the regions A2 is approximately the same as the height of the upper surface of the protrusion portion 11. Here, the insulation film 40 is also removed, and a recessed portion is formed on the upper surface of the protrusion portion 11, but the upper surface of the protrusion portion 11 is approximately flat.

In addition, each projection portion 22 becomes smaller due to the difference in etching rate. Since the etching rate of the projection portion 22 is faster, the projection portion 22 shown in FIG. 1F is smaller by the etching compared to the process shown in FIG. 1E. This makes it possible to form an approximately flat structure in which the projection portion 22 projects slightly.

Next, as shown in FIG. 1G, an insulation film 60 is formed on the protrusion portion 11. The insulation film 60 is formed by, for example, an oxidation treatment. The insulation film 60 is, for example, an oxide film. The insulation film 60 functions as a gate oxide film.

Next, as shown in FIG. 1H, a conductive film 70 is formed on the insulation film 20 and the insulation film 60. The conductive film 70 functions as a gate electrode. The conductive film 70 is, for example, a gate poly LPCVD (low-pressure CVD) film.

Next, as shown in FIG. 1I, part of the conductive film 70 is removed. Thereby, the conductive film 70 is formed on the insulation film 60. The part of the conductive film 70 is removed by, for example, CDE (chemical dry etching).

As shown in FIG. 1I, the insulation film 20 is provided on the face F1 in the regions A2. The height of the upper surface of the insulation film 20 is substantially the same as the height of the upper surface of the protrusion portion 11. The projection portion 22 projects from the upper surface of the insulation film 20 around the protrusion portion 11 to the opposite side of the semiconductor substrate 10.

As described above, according to the first embodiment, the insulation film 20 is formed, on the face F1, so that the film thickness at each step portion (side portion) of the protrusion portion 11 is thinner than the film thickness at the upper surface of the protrusion portion 11 or the regions A2. In addition, part of the insulation film 20 is removed using the resist 30 as a mask, and thereby the opening portion 21 and the projection portions 22 are formed. Furthermore, the insulation film 50 is removed together with part of the projection portion 22. This makes it possible to lower the steps (height of the projection portions 22) of the insulation film 20 and reduce side etching. In addition, reducing side etching makes it possible to prevent the guard ring (semiconductor layer 12) for canceling electric charge from being wider. This makes it possible to prevent the extension of the termination length. This also makes it possible to form an approximately flat structure at low cost without using CMP (chemical mechanical polishing) or the like. This then makes it possible to more appropriately form a flat structure in the termination region.

Next, a comparative example of the first embodiment will be described.

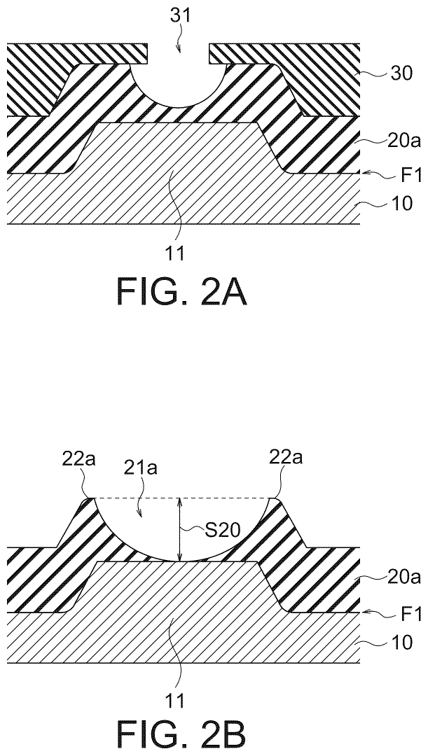

FIGS. 2A and 2B are cross-sectional views showing an example of a semiconductor device manufacturing method according to a first comparative example of the first embodiment. The first comparative example of the first embodiment differs from the first embodiment in that an insulation film 20a is formed instead of the insulation film 20. Note that the semiconductor layer 12 is omitted in FIGS. 2A and 2B.

FIG. 2A shows the same process as that shown in FIG. 1B according to the first embodiment in the case in which the insulation film 20a is formed instead of the insulation film 20. The insulation film 20a is, for example, a TEOS film. Compared to the insulation film 20, the insulation film 20a is formed conformally along the shape of the face F1. Therefore, in the vicinity of the step portions of the protrusion portion 11, the film thickness of the insulation film 20a is larger than the film thickness of the insulation film 20 according to the first embodiment. Here, FIG. 2A shows the etching in progress.

Next, as shown in FIG. 2B, the etching is stopped midway and the resist 30 is removed. The timing for stopping the etching is when the opening portion 21a reaches the upper surface of the protrusion portion 11. In this case, a large step S20 (the height of the projection portions 22a) of the insulation film 20a remains. In the example shown in FIG. 2B, the height of the step S20 corresponds to the thickness of the insulation film 20a. As a result, there may be residues in processing and opening defects in the lithography process.

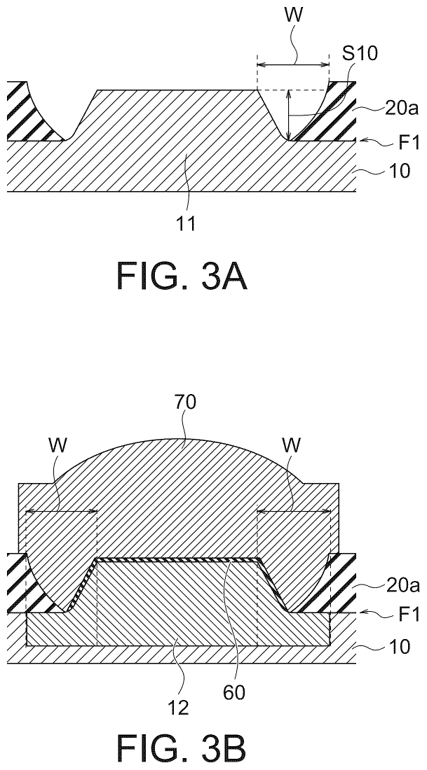

FIGS. 3A and 3B are cross-sectional views showing an example of a semiconductor device manufacturing method according to a second comparative example of the first embodiment. A second comparative example of the first embodiment differs from the first comparative example of the first embodiment in that etching is performed until the projection portions 22a disappear. Note that the semiconductor layer 12 is omitted in FIG. 3A.

The etching is continued as in the process shown in FIG. 2A and etching is performed until the projection portions 22a disappear as shown in FIG. 3A, and the resist 30 is removed. In this case, steps S10 occur on the semiconductor substrate 10. In addition, a side etching width W is large.

Next, as shown in FIG. 3B, an insulation film 60 is formed on the protrusion portion 11, a conductive film 70 is formed on the insulation film 20 and the insulation film 60, and part of the conductive film 70 is removed. The process shown in FIG. 3B is the same as the process shown in FIG. 1G to FIG. 1I according to the first embodiment. In the example shown in FIG. 3B, the side etching width W, which is an unnecessary width, increases. As a result, the conductive film 70 is buried in the portions of the steps S10. In this case, the guard ring (semiconductor layer 12) needs to be widened, and the termination length will increase.

In contrast to the above comparative examples, in the first embodiment, the steps of the insulation film 20 (the height of the projection portions 22) can be lowered and side etching can be reduced in a state in which the insulation film 20, which has been in contact with the upper surface of the protrusion portion 11, is completely removed. In addition, reducing side etching makes it possible to prevent the guard ring (semiconductor layer 12) for canceling electric charge from being wider. This makes it possible to prevent the extension of the termination length.

### Second Embodiment

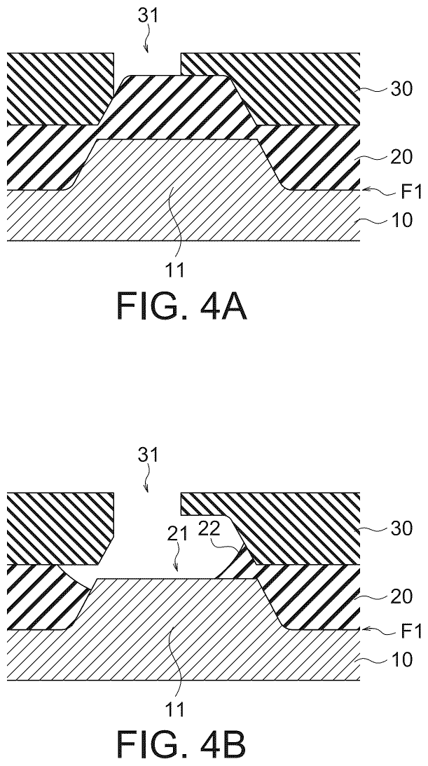

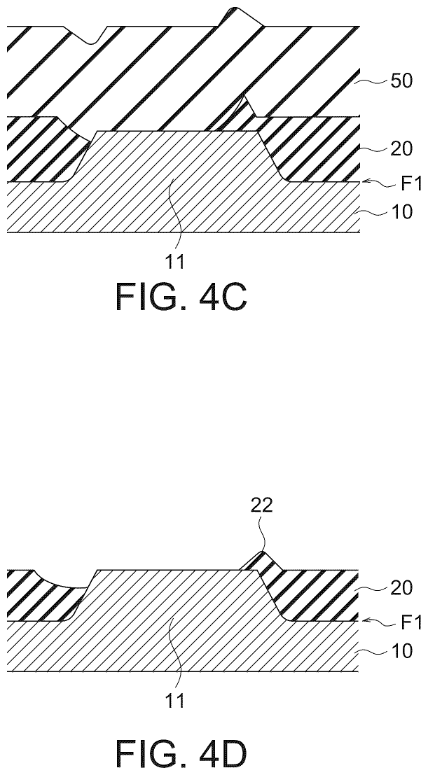

FIGS. 4A to 4D are cross-sectional views showing an example of a semiconductor device manufacturing method according to a second embodiment. The second embodiment differs from the first embodiment in that a mask misalignment occurs. In other words, the second embodiment is an example for describing a case in which a mask misalignment occurs. Note that the semiconductor layer 12 is omitted in FIGS. 4A to 4D.

After the insulation film 20 is formed (see FIG. 1A), as shown in FIG. 4A, a resist 30 is formed on the insulation film 20, and part of the resist 30 is removed. In the second embodiment, the misalignment causes the center of an opening portion 31 of the resist 30 to be shifted from the center of the protrusion portion 11.

Next, as shown in FIG. 4B, part of the insulation film 20 is removed to form an opening portion 21 and a projection portion 22 of the insulation film 20. Due to misalignment, etching progresses slowly to the right of the opening portion 31 and quickly to the left of the opening portion 31. Therefore, the projection portion 22 is not formed to the left of the opening portion 31, and the side etching occurs slightly. The projection portion 22 to the right of the opening portion 31 is higher than the projection portion 22 in the first embodiment.

Next, as shown in FIG. 4C, the resist 30 is removed, and an insulation film 50 is formed on the protrusion portion 11 and the insulation film 20. Note that the formation of the insulation film 40 is omitted.

Next, as shown in FIG. 4D, the insulation film 50 is removed together with part of the projection portion 22. As shown in FIG. 4D, the side etching occurs slightly due to misalignment.

Next, a comparative example of the second embodiment will be described.

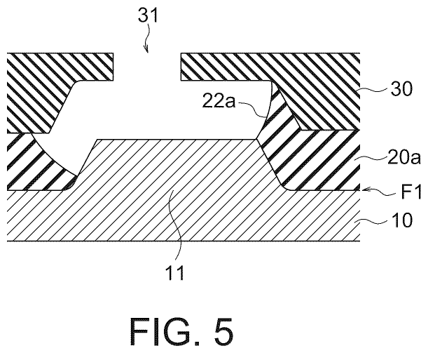

FIG. 5 is a cross-sectional view showing an example of a semiconductor device manufacturing method according to a first comparative example of the second embodiment. The first comparative example of the second embodiment differs from the second embodiment in that an insulation film 20a is formed instead of the insulation film 20. Note that the semiconductor layer 12 is omitted in FIG. 5.

When the insulation film 20a is formed instead of the insulation film 20, the projection portion 22a on the right side of the opening portion 31 is higher than the projection portion 22 according to the second embodiment. In addition, since the etching amount of the insulation film 20a is large, the amount of side etching on the left side of the opening portion 31 is also large.

In contrast to the above comparative example, in the second embodiment, even when misalignment occurs, the step of the insulation film 20 (the height of the projection portion 22) can be lowered, and the side etching can be reduced. In addition, in the second embodiment, the etching amount of the insulation film 20 is smaller than in the comparative example.

As in the second embodiment, misalignment of the mask may occur. The semiconductor device manufacturing method according to the second embodiment can obtain the same effect as the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device manufacturing method comprising:
forming a semiconductor layer of a first conductivity type on a protrusion portion of a semiconductor substrate having a first face and the protrusion portion provided in a first region of the first face;
forming a first insulation film, on the first face, such that a film thickness of the first insulation film at a step portion of the protrusion portion is thinner than a film thickness of the first insulation film at an upper surface of the protrusion portion or a film thickness of the first insulation film at a second region of the first face different from the first region;
forming a mask material on the first insulation film;
removing the mask material above the protrusion portion;
removing part of the first insulation film using the mask material as a mask to form an opening portion of the first insulation film and a projection portion of the first insulation film, the opening portion exposing an upper surface of the protrusion portion, the projection portion projecting from an edge portion of the opening portion to an opposite side of the semiconductor substrate;
forming a second insulation film on the protrusion portion and the first insulation film; and
removing the second insulation film together with part of the projection portion.

2. The semiconductor device manufacturing method according to claim 1, further comprising:
after removing the second insulation film;
forming a third insulation film on the protrusion portion; and
forming a conductive film on the third insulation film.

3. The semiconductor device manufacturing method according to claim 1, wherein the forming the first insulation film includes forming the first insulation film by an HDP (high density plasma) method.

4. The semiconductor device manufacturing method according to claim 1, wherein the removing the part of the first insulation film includes performing isotropic etching using the mask material as a mask.

5. The semiconductor device manufacturing method according to claim 1, wherein the first region and the second region are termination regions.

6. The semiconductor device manufacturing method according to claim 3, wherein the removing the part of the first insulation film includes performing isotropic etching using the mask material as a mask.

7. The semiconductor device manufacturing method according to claim 3, wherein the first region and the second region are termination regions.

8. The semiconductor device manufacturing method according to claim 4, wherein the first region and the second region are termination regions.

9. The semiconductor device manufacturing method according to claim 6, wherein the first region and the second region are termination regions.

10. A semiconductor device, comprising:
a semiconductor substrate having a first face and a protrusion portion provided in a first region of the first face; and
a first insulation film provided on the first face in a second region of the first face different from the first region,
wherein the first insulation film has a projection portion projecting from an upper surface of the first insulation film around the protrusion portion to an opposite side of the semiconductor substrate.

11. The semiconductor device according to claim 10, wherein:
the semiconductor substrate further including a semiconductor layer of a first conductivity type provided on the protrusion portion; and
the semiconductor device further comprising:
a third insulation film provided on the protrusion portion; and
a conductive film provided on the third insulation film.

12. The semiconductor device according to claim 10, wherein a height of an upper surface of the first insulation film is substantially the same as a height of an upper surface of the protrusion portion.

13. The semiconductor device according to claim 11, wherein a height of an upper surface of the first insulation film is substantially the same as a height of an upper surface of the protrusion portion.
